(19) United States
(12) Patent Application Publication
(10) Pub. No.: US 2025/0241095 A1
(43) Pub. Date: Jul. 24, 2025

(54) LIGHT-EMITTING DEVICE

(71) Applicant: NICHIA CORPORATION, Anan-shi (JP)

(72) Inventors: Takuhiro FURUKAWA, Komatsushima-shi (JP); Shinya MITSUHASHI, Tokushima-shi (JP); Yuji AKAZAWA, Tokushima-shi (JP)

(21) Appl. No.: 19/008,358

(22) Filed: Jan. 2, 2025

(30) Foreign Application Priority Data
Jan. 18, 2024 (JP) 2024-005745

(51) Int. Cl. H10H 20/854

(52) U.S. Cl. CPC H10H 20/854

(57) ABSTRACT

A light-emitting device includes a light-emitting element, a light-transmissive member, a silicone resin member, and an intermediate layer. The light-transmissive member is disposed on an upper surface of the light-emitting element and contains oxygen atoms. The silicone resin member covers the light-transmissive member such that at least a portion of an upper surface of the light-transmissive member is exposed. The intermediate layer is disposed between the light-transmissive member and the silicone resin member. The intermediate layer is made of a silane coupling agent.

### CROSS-REFERENCE TO RELATED APPLICATIONS

The present application claims priority under 35 U. S. C. § 119 to Japanese Patent Application No. 2024-005745, filed Jan. 18, 2024, the content of which is hereby incorporated herein by reference in its entirety.

### TECHNICAL FIELD

The present disclosure relates to a light-emitting device and an optical member.

### BACKGROUND

There is known a light-emitting device including a light-emitting element and a light-transmissive member such as a wavelength conversion member, in which a white resin such as a silicone resin surrounds the light-transmissive member (Japanese Patent PublicationNo.2017-011259 A).

### SUMMARY

An object of the present disclosure is to provide a light-emitting device and an optical member having superior adhesion between a light-transmissive member and a silicone resin member.

The present disclosure includes the following configurations.

A light-emitting device includes a light-emitting element, a light-transmissive member, a silicone resin member, and an intermediate layer. The light-transmissive member is disposed on an upper surface of the light-emitting element and contains oxygen atoms. The silicone resin member covers the light-transmissive member such that at least a portion of an upper surface of the light-transmissive member is exposed. The intermediate layer is disposed between the light-transmissive member and the silicone resin member. The intermediate layer is made of a silane coupling agent. Alternatively, a light-emitting device includes a light-emitting element, a light-transmissive member, a silicone resin member, and an intermediate layer. The light-transmissive member is disposed on an upper surface of the light-emitting element and contains oxygen atoms. The silicone resin member covers the light-transmissive member such that at least a portion of an upper surface of the light-transmissive member is exposed. The intermediate layer is disposed between the light-transmissive member and the silicone resin member. The intermediate layer is made of an oxide film or oxide particles.

An optical member includes a light-transmissive member containing oxygen atoms, a silicone resin member covering at least a part of a surface of the light-transmissive member, and an intermediate layer disposed between the light-transmissive member and the silicone resin member, the intermediate layer being made of a silane coupling agent.

Alternatively, an optical member includes a light-transmissive member containing oxygen atoms, a silicone resin member covering the light-transmissive member such that at least a portion of an upper surface of the light-transmissive member is exposed, and an intermediate layer disposed between the light-transmissive member and the silicone resin member, the intermediate layer being made of an oxide film or oxide particles.

According to embodiments of the present disclosure, a light-emitting device and an optical member having superior adhesion between a light-transmissive member and a silicone resin member can be provided.

### BRIEF DESCRIPTION OF THE DRAWINGS

FIG. 1A is a schematic perspective view illustrating a light-emitting device according to an embodiment.

FIG. 1B is a schematic top view illustrating the light-emitting device according to the embodiment.

FIG. 1C is a cross-sectional view schematically illustrating a cross-section taken along line IC-IC of FIG. 1B.

FIG. 2A is a schematic top view illustrating a light-emitting device according to an embodiment.

FIG. 2B is a schematic cross-sectional view illustrating a cross-section taken along line IIB-IIB of FIG. 2A.

FIG. 3A is a schematic top view illustrating a light-emitting device according to an embodiment.

FIG. 3B is a schematic cross-sectional view illustrating a cross-section taken along line IIIB-IIIB of FIG. 3A.

FIG. 4 is a schematic cross-sectional view illustrating a light-emitting device according to an embodiment.

FIG. 5 is a schematic cross-sectional view illustrating a light-emitting device according to an embodiment.

FIG. 6A is a schematic perspective view illustrating an optical member according to an embodiment.

FIG. 6B is a schematic cross-sectional view illustrating an optical member according to an embodiment.

FIG. 6C is a schematic perspective view illustrating an optical member according to an embodiment.

FIG. 6D is a schematic cross-sectional view illustrating an optical member according to an embodiment.

FIG. 6E is a schematic perspective view illustrating an optical member according to the embodiment.

FIG. 6F is a schematic cross-sectional view illustrating an optical member according to an embodiment.

### DETAILED DESCRIPTION

Embodiments are described below with reference to the drawings. The following embodiments exemplify a light-emitting device and an optical device for realizing the technical concept of the present embodiment, but the present disclosure is not limited to the following embodiments. Unless otherwise specified, dimensions, materials, shapes, relative arrangements, or the like of components described in the embodiments are not intended to limit the scope of the present invention thereto and are merely exemplary. Sizes, positional relationships, and the like of members illustrated in the drawings can be exaggerated or simplified for clarity of description. To avoid overcomplicating the drawings, some elements may be omitted, or end views illustrating only cut surfaces may be used as cross-sectional views.

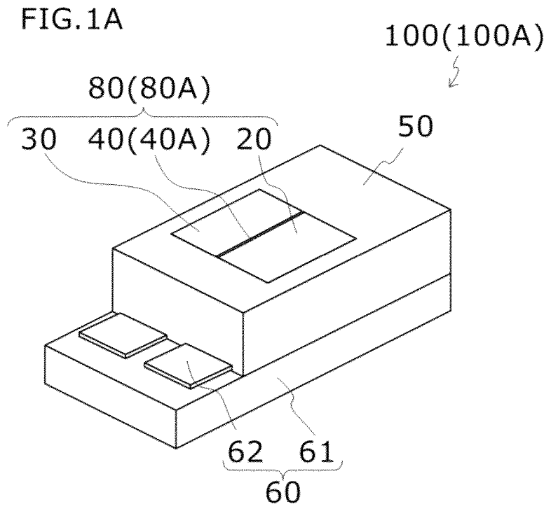

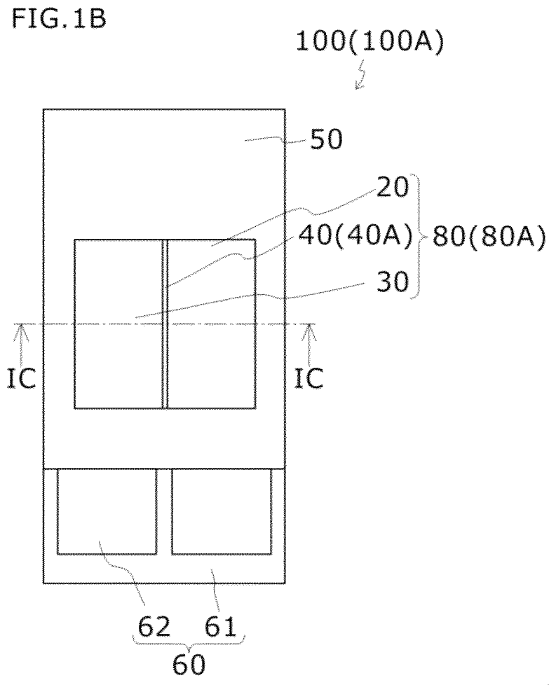

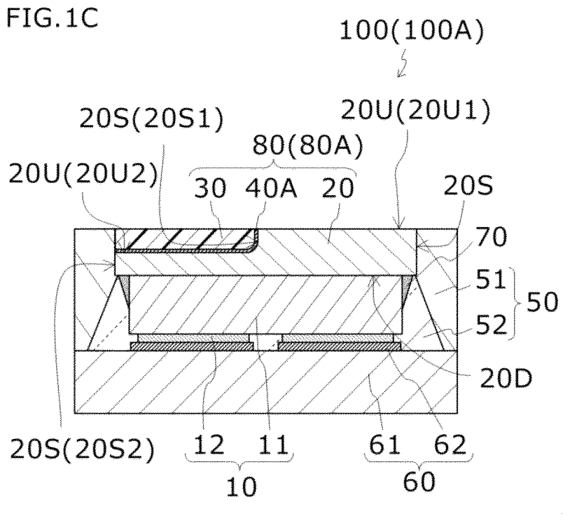

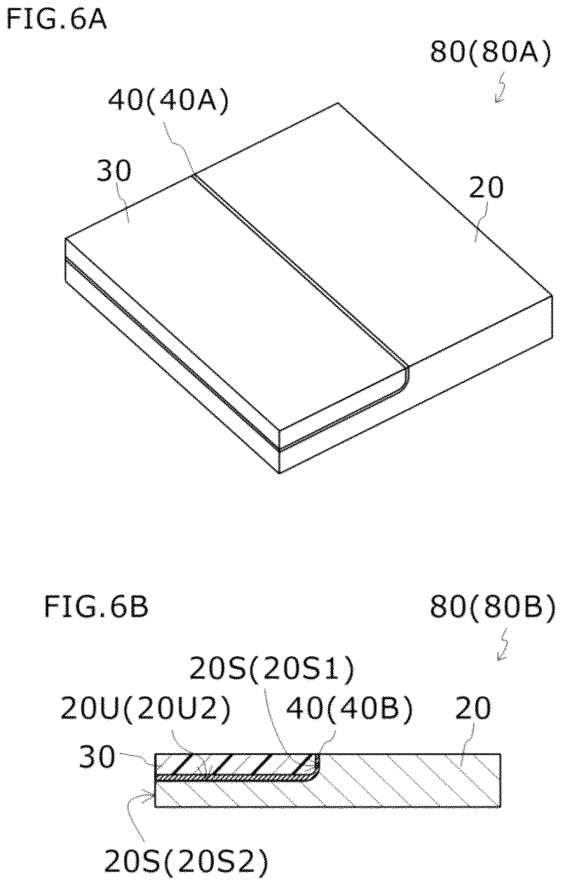

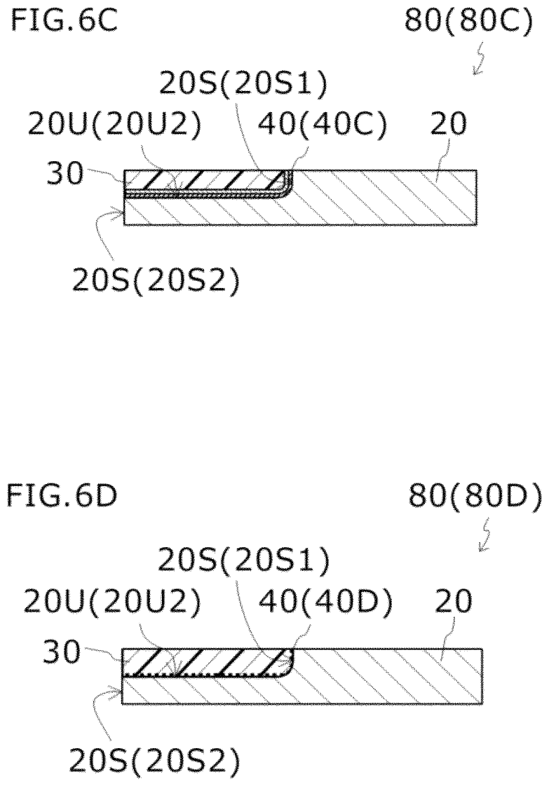

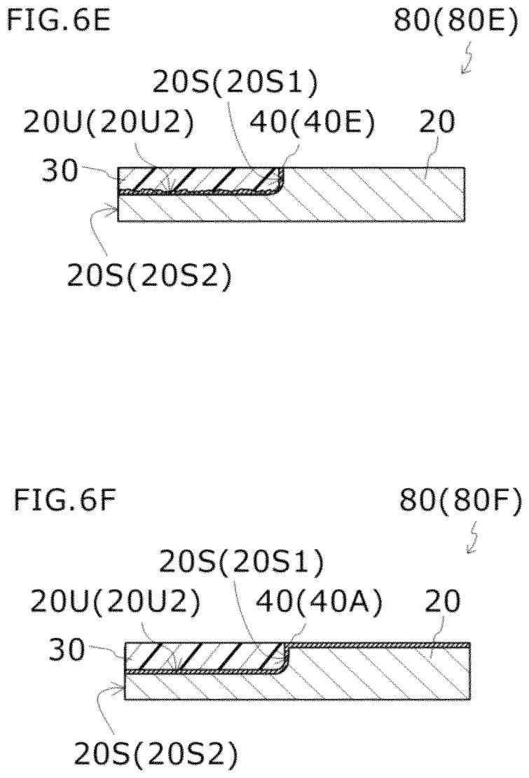

FIGS. 1A to 5 are schematic views each illustrating a light-emitting device according to several embodiments. FIGS. 6A to 6F are schematic views each illustrating an optical member according to several embodiments.

The light-emitting device 100 includes a light-emitting element 10, a light-transmissive member 20, a silicone resin member 30, and an intermediate layer 40. The light-transmissive member 20 is disposed on an upper surface of the light-emitting element 10. The light-transmissive member 20 contains oxygen atoms. The silicone resin member 30 covers the light-transmissive member 20 such that at least a portion of an upper surface of the light-transmissive member 20 is exposed. The intermediate layer 40 is disposed between the light-transmissive member 20 and the silicone resin member 30.

A silane coupling agent can be used as the intermediate layer 40. Adhesion between the intermediate layer 40 and the light-transmissive member 20 can be improved by chemically bonding silicon (Si) in the silane coupling agent and oxygen (O) in the light-transmissive member 20 to each other. Here, as oxygen used for chemical bonding, oxygen contained in the air may be used in addition to oxygen in the light-transmissive member 20.

The adhesion between the intermediate layer 40 and the silicone resin member 30 can be improved by chemically bonding the hydrolyzable alkoxy group of the silane coupling agent and the silanol group in the silicone resin member to each other. Examples of the hydrolyzable alkoxy group include a methoxy type, an ethoxy type, a dimethoxy type, and a trimethoxy type.

Alternatively, an oxide such as an oxide film or oxide particles can be used as the intermediate layer 40. The principle of adhesion between the light-transmissive member 20 and the intermediate layer 40 varies depending on a method of forming the intermediate layer 40. For example, when the oxide film or the oxide particles are formed by an atomic deposition method (ALD method), a metal atom chemical bonding is formed between an oxygen atom of a hydroxyl group on the surface of the light-transmissive member 20 and an oxygen atom of the oxide film or the oxide particles. When the oxide film or oxide particles are formed through sputtering, a high voltage is applied to a target containing an oxide and the light-transmissive member 20 so that an ionized inert gas (such as Ar) in a chamber hits the target at a high speed, and the oxide particles generated by sputtering phenomenon are attached to the light-transmissive member 20. This can improve the adhesion between the intermediate layer 40 and the light-transmissive member 20.

The adhesion between the intermediate layer 40 and the silicone resin member 30 can be improved by hydrogen-bonding the hydroxyl group generated on the oxide surface and hydrogen in the silicone resin member 30 to each other. At least one selected from the group consisting of aluminum oxide (Al₂O₃), silicon oxide (SiO₂), and indium tin oxide (ITO) can be used as the oxide.

As in a light-emitting device 100A illustrated in FIG. 1C, the light-emitting device 100 can further include a bonding member 70 that bonds the light-emitting element 10 and the light-transmissive member 20 to each other. As illustrated in the light-emitting device 100A, a substrate 60 on which the light-emitting element 10 is mounted can be further included. The substrate 60 and the light-emitting element 10 are bonded to each other with a conductive bonding member (not illustrated).

FIG. 6A is a schematic perspective view illustrating an optical member 80 according to the embodiment. The optical member 80 is a member that can constitute a portion of the light-emitting device 100. The optical member 80 includes the light-transmissive member 20, the silicone resin member 30, and the intermediate layer 40. The light-transmissive member 20 contains oxygen atoms. The silicone resin member 30 covers the light-transmissive member 20 such that at least a portion of an upper surface of the light-transmissive member 20 is exposed. The intermediate layer 40 is disposed between the light-transmissive member 20 and the silicone resin member 30. The intermediate layer 40 is a member that can improve the adhesion between the light-transmissive member 20 and the silicone resin member 30. The details thereof are the same as those of the light-emitting device 100, and thus will not be described.

Each configuration of the light-emitting device and the optical member will be described in detail below with reference to the drawings.

### Light-Emitting Element

The light-emitting device 100 includes one or more of the light-emitting elements 10. A semiconductor light-emitting element, such as a light-emitting diode, can be used as the light-emitting element 10. The light-emitting element 10 includes a semiconductor layered body 11 and a pair of positive and negative electrodes 12. The semiconductor layered body 11 includes, for example, an element substrate made of sapphire or the like and a semiconductor layer formed thereon. Alternatively, the semiconductor layered body 11 can be formed of only the semiconductor layer without including the element substrate. A shape of the light-emitting element 10 in a top view can be a polygonal shape, such as a triangular shape, a quadrangular shape, or a hexagonal shape. The size of the light-emitting element 10 can be, for example, in a range from 100 μm to 3000 μm on one side in a top view. Specifically, the light-emitting element 10 can be square having a side of about 600 μm, about 1000 μm, about 1400 μm, about 1700 μm, or the like. The light-emitting element 10 may be rectangular and have a long side and a short side in a top view. The size of the light-emitting element 10 can be, for example, 1100 μm×200 μm. When a plurality of the light-emitting elements 10 are included, each of the light-emitting elements 10 may have the same size, emission wavelength, composition, or the like, or some or all thereof may be different from each other. All of the plurality of light-emitting elements 10 can be connected in series or in parallel, and can be connected such that the series connections and parallel connections are mixed.

The semiconductor layered body 11 includes an n-type semiconductor layer, a p-type semiconductor layer, and a light-emitting layer interposed therebetween. The semiconductor layered body including such a light-emitting layer is, for example, In_{X}Al_{Y}Ga_{1-X-Y}N (0≤x, 0≤y, and x+y≤1).

The semiconductor layered body 11 may have a structure including one or more light-emitting layers between the n-type semiconductor layer and the p-type semiconductor layer or may have a structure in which a structure sequentially including the n-type semiconductor layer, the light-emitting layer, and the p-type semiconductor layer is repeated a plurality of times. When the semiconductor layered body 11 includes the plurality of light-emitting layers, the semiconductor layered body may include the light-emitting layers having different light emission peak wavelengths, or may include the light-emitting layers having the same light emission peak wavelength. Note that having the same emission peak wavelength includes a case in which there is a variation of about a few nm. A combination of emission peak wavelengths between the plurality of light-emitting layers can be selected as appropriate. For example, when the semiconductor layered body includes two light-emitting layers, light-emitting layers can be selected in combination of blue light and blue light, green light and green light, red light and red light, ultraviolet light and ultraviolet light, blue light and green light, blue light and red light, or green light and red light.

The light-emitting element 10 includes the pair of positive and negative electrodes 12 on a lower surface of the semiconductor layered body 11. A good electrical conductor can be used as the electrode 12, and the electrode 12 can be made of gold, silver, tin, platinum, rhodium, titanium, aluminum, tungsten, palladium, nickel, or an alloy thereof. The electrode 12 can include an ohmic electrode in contact with the lower surface of the semiconductor layered body 11 and a pad electrode connected to the ohmic electrode and connected to the outside. The thickness of the electrode can be, for example, in a range from 10 μm to 50 μm.

### Light-Transmissive Member

The light-transmissive member 20 contains oxygen atoms. The light-transmissive member 20 is a light-transmissive member disposed so as to cover an upper surface of the semiconductor layered body 11 of the light-emitting element 10. Light emitted from the light-emitting element 10 is emitted to the outside through the light-transmissive member 20. In the light-emitting device 100 illustrated in FIG. 1C, an upper surface 20U of the light-transmissive member 20 includes a first upper surface 20U1 and a second upper surface 20U2 located below the first upper surface 20U1. A lower surface 20D opposite to the upper surface 20U of the light-transmissive member 20 faces the upper surface of the light-emitting element 10 directly or via the bonding member 70. A lateral surface 20S is included between the upper surface 20U and the lower surface 20D of the light-transmissive member 20. In the example illustrated in FIG. 1C, a first lateral surface 20S1 is included between the first upper surface 20U1 and the second upper surface 20U2, and a second lateral surface 20S2 is included between the second upper surface 20U2 and the lower surface 20D.

In the example illustrated in FIG. 1B, the silicone resin member 30 disposed on the second upper surface 20U2 of the light-transmissive member 20 and the first upper surface 20U1 have the same area and the same shape. That is, since the second upper surface 20U2 of the light-transmissive member 20 and the silicone resin member 30 have the same area and the same size, the first upper surface 20U1 and the second upper surface 20U2 have the same area and the same shape. The upper surface 20U of the light-transmissive member 20 is square as a whole, and each of the first upper surface 20U1 and the second upper surface 20U2 is rectangular in a top view. The first upper surface 20U1 is exposed to the outside. Thus, the first upper surface 20U1 can be a high-luminance light-emitting region that can emit high-luminance light. The second upper surface 20U2 is covered with the silicone resin member 30. Thus, a portion of light emitted from the second upper surface 20U2 can be reflected to be guided to the first upper surface 20U1 side, and emitted from the first upper surface 20U1. That is, an upper surface of the silicone resin member 30 disposed above the second upper surface 20U2 can be a low-luminance light-emitting region that can emit light having luminance lower than that of light emitted from the first upper surface 20U1. The area of the second upper surface 20U2 is preferably, for example, in a range from 35% to 95% of the area of the entire upper surface 20U of the light-transmissive member 20. The luminance of the low-luminance light-emitting region can be, for example, in a range from 5% to 80% of the luminance of the high-luminance light-emitting region. By including the high-luminance light-emitting region and the low-luminance light-emitting region as described above, for example, when the light-emitting device 100 is used as a headlight of a vehicle, a high-luminance region can be included in a desired region of an irradiation region. That is, since the desired light distribution can be obtained without using complex optical design such as reflectors and lenses, the size of the headlight can be reduced, and the design of the headlight can be further enhanced.

The first upper surface 20U1 and the second upper surface 20U2 of the light-transmissive member 20 may have different areas or different shapes. The height of the second upper surface 20U2 (the height from the lower surface 20D of the light-transmissive member 20) of the light-transmissive member 20 can be in a range from 20% to 90% of the height of the first upper surface 20U1 (the height from the lower surface 20D of the light-transmissive member 20). Thus, even when the second upper surface 20U2 is covered with the silicone resin member 30, light can be emitted to the outside through the silicone resin member 30.

The first lateral surface 20S1 and the second upper surface 20U2 may be flat surfaces perpendicularly contiguous with each other, or the first lateral surface 20S1 and/or the second upper surface 20U2 may include an inclined surface or a curved surface and the first lateral surface 20S1 and the second upper surface 20U2 may be contiguous with each other through the inclined surface or the curved surface. In the light-transmissive member 20 illustrated in FIG. 1C and the like, the second upper surface 20U2 includes the curved surface between the first lateral surface 20S1 and the second upper surface 20U2. This makes it easier to propagate the light on the second upper surface 20U2 side to the first upper surface 20U1 side, and to further increase the luminance of the first upper surface 20U1 side in a top view. The curved surface is a recessed surface that is recessed to the light-transmissive member 20 side. The curvature radius of the curved surface is, for example, in a range from 5 μm to 35 μm.

The lateral surface 20S (first lateral surface 20S1) continuous with the first upper surface 20U1 is preferably a surface perpendicular to the first upper surface 20U1 in a portion continuous with the first upper surface 20U1. This can clarify the luminance difference between a light-emitting region on the upper surface of the light-emitting device 100 and a region surrounding the light-emitting region.

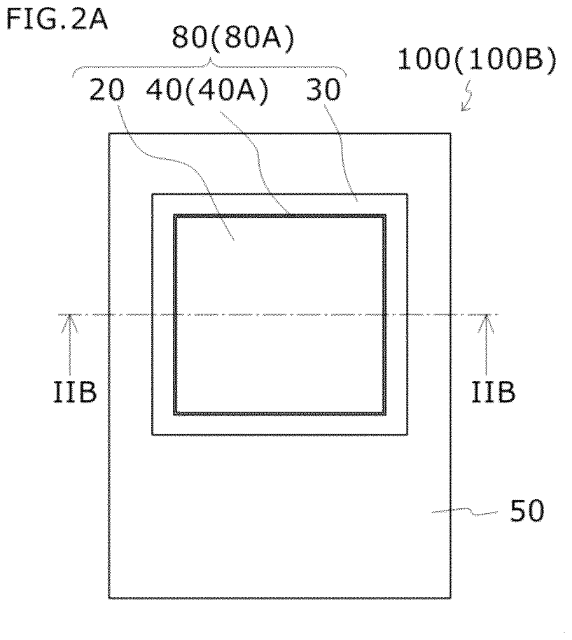

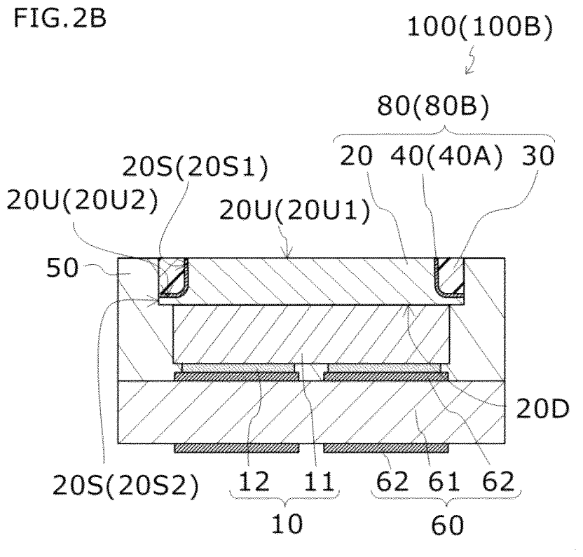

In a light-emitting device 100B illustrated in FIGS. 2A and 2B, in the light-transmissive member 20 in a top view, the first upper surface 20U1 is located at the center and the second upper surface 20U2 surrounds the first upper surface 20U1. The size of the first upper surface 20U1 in a top view can be in a range from 50% to 100% of the area of the upper surface of the light-emitting element 10. The height of the second upper surface 20U2 (the height from the lower surface 20D of the light-transmissive member 20) of the light-transmissive member 20 can be in a range from 5% to 40% of the height of the first upper surface 20U1 (the height from the lower surface 20D of the light-transmissive member 20). Thus, light is blocked by the silicone resin member 30 disposed on the second upper surface 20U2, and the silicone resin member 30 does not contribute as a light-emitting surface. That is, only the first upper surface 20U1 can be used as the light-emitting surface. The second upper surface 20U2 need not be located on the entirety of outer periphery of the first upper surface 20U1. For example, when the light-transmissive member 20 is rectangular in a top view, the light-transmissive member 20 can be formed to have a shape in which the second upper surface 20U2 is located on the long side of the first upper surface 20U1, and the second upper surface 20U2 is not located on the short side of the first upper surface 20U1.

As described above, in the light-transmissive member 20 including the first upper surface 20U1 and the second upper surface 20U2, by adjusting the height of the second upper surface 20U2, reflectance (transmittance) of the silicone resin member 30, or the like, the silicone resin member 30 disposed on the second upper surface 20U2 can be set as the low-luminance light-emitting region or a light-shielding region.

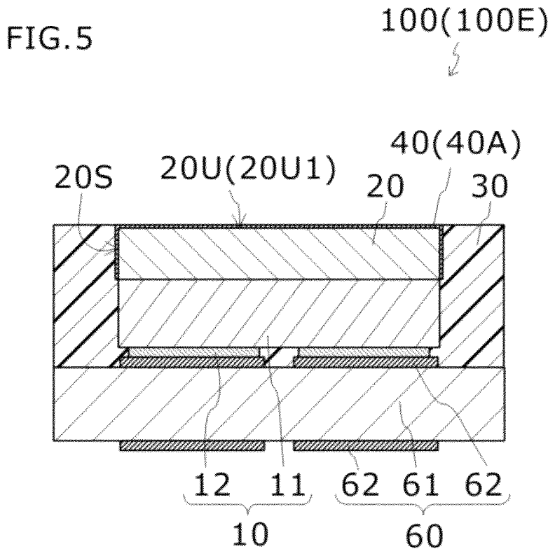

In a light-emitting device 100E illustrated in FIG. 5, the upper surface 20U of the light-transmissive member 20 does not include the second upper surface but includes only the first upper surface 20U1. In the example illustrated in FIG. 5, the light-transmissive member 20 has the same area and shape as those of the light-emitting element 10 in a top view. Not limited thereto, the light-transmissive member 20 can be formed to have a different shape and a different size from those of the light-emitting element 10 in a top view.

As the light-transmissive member 20, a resin member, an inorganic member, glass, or a combination thereof can be used. The light-transmissive member 20 preferably has light transmittance of 60% or more, more preferably 70% or more, and still more preferably 80% or more at the peak wavelength of the light emitted from the light-emitting element 10.

The light-transmissive member 20 contains oxygen atoms. Examples of the resin member that can be used include thermosetting resins, such as a silicone resin, a silicone-modified resin, an epoxy resin, and a phenol resin; and thermoplastic resins, such as a polycarbonate resin, an acrylic resin, a methylpentene resin, and a polynorbornene resin. Particularly, a silicone resin with superior light resistance and heat resistance is suitable. In the light-transmissive member 20, silicon oxide, aluminum oxide, or the like can be used as an inorganic member. Alkali-free glass, soda glass, soda lime glass, borosilicate glass, aluminosilicate glass, quartz glass, low-alkali borosilicate glass, or the like can be used as the glass. The light-transmissive member 20 need not contain oxygen.

The light-transmissive member 20 may include only the light-transmissive member described above, or may include the light-transmissive member as a base material, containing a phosphor that is excited by light from the light-emitting element and converts the light into light having a different wavelength, a light scattering agent, or the like. By containing the phosphor, a light-emitting device that can emit white light can be obtained.

As the phosphor, an yttrium-aluminum-garnet phosphor, a lutetium-aluminum-garnet phosphor, a terbium-aluminum-garnet phosphor, a CCA phosphor, a SAE phosphor, a chlorosilicate phosphor, a silicate phosphor, an oxynitride phosphor, such as a β-SiAlON phosphor or α-SiAlON phosphor, a nitride phosphor, such as an LSN phosphor, a BSESN phosphor, an SLA phosphor, a CASN phosphor, or a SCASN phosphor, a fluoride phosphor, such as a KSF phosphor, a KSAF phosphor, or an MGF phosphor, a quantum-dot having a perovskite structure, a II-VI group quantum-dot, a III-V group quantum-dot, or a quantum-dot having a chalcopyrite structure can be used, for example.

As the light scattering agent, particles of titanium oxide, silicon oxide, aluminum oxide, zinc oxide, magnesium oxide, zirconium oxide, yttrium oxide, calcium fluoride, magnesium fluoride, niobium pentoxide, barium titanate, tantalum pentoxide, barium sulfate, glass, or the like can be used, for example.

The light-transmissive member 20 can be bonded to the light-emitting element 10 by using the bonding member 70 having light-transmissivity. The light-emitting element 10 and the light-transmissive member 20 can be directly bonded to each other through a direct bonding method or the like without using a bonding member.

### Silicone Resin Member

The silicone resin member 30 has light reflectivity. Alternatively, the silicone resin member 30 has light reflectivity and light transmissivity. The silicone resin member 30 covers a portion of the surface of the light-transmissive member 20 via the intermediate layer 40 described later. In the example illustrated in FIG. 1C and FIG. 2B, the silicone resin member 30 covers the second upper surface 20U2 and the first lateral surface 20S1 of the light-transmissive member 20 via the intermediate layer 40.

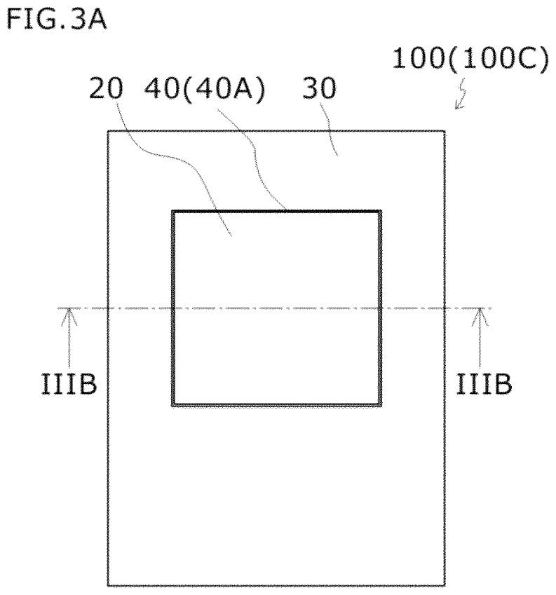

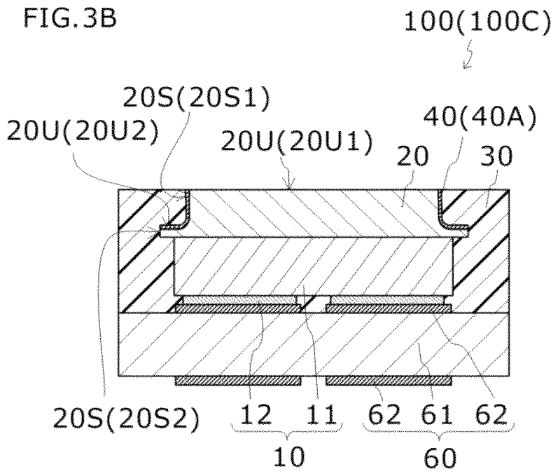

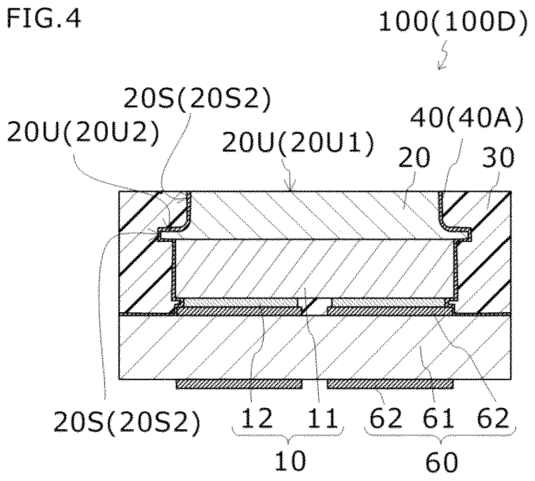

In a light-emitting device 100C illustrated in FIG. 3B, the silicone resin member 30 covers the light-emitting element 10 and the substrate 60 in addition to the portion of the surface of the light-transmissive member 20. The silicone resin member 30 of the light-emitting device 100B is disposed to be in contact with the light-emitting element 10 and the substrate 60. Also, in a light-emitting device 100D illustrated in FIG. 4, the silicone resin member 30 covers the light-emitting element 10 and the substrate 60 in addition to the portion of the surface of the light-transmissive member 20. In the light-emitting device 100D, the intermediate layer 40 is disposed between the light-emitting element 10 and the substrate 60, and the silicone resin member 30.

The silicone resin member 30 contains a silicone resin and particles of a light reflective material. Examples of the silicone resin include a silicone resin, and a modified silicone resin. A condensation type silicone or an addition type silicone can be used as the silicone resin. Particularly, a condensation type silicone having good heat resistance and light resistance is preferable. Examples of the light reflective material include titanium oxide, silicon oxide, zirconium oxide, magnesium oxide, calcium carbonate, calcium hydroxide, calcium silicate, zinc oxide, barium titanate, potassium titanate, aluminum oxide, aluminum nitride, boron nitride, and mullite, and a combination thereof. Among these materials, titanium oxide is preferable because it is relatively stable with respect to moisture or the like and has a high refractive index.

The concentration of the light reflective material is preferably in a range from 60 mass % to 70 mass %. The silicone resin member 30 preferably has reflectance, for example, in a range from 1% to 95% at the emission peak wavelength of the light emitted from the light-emitting element 10. Preferably, the total transmittance of the silicone resin member 30 is in a range from 1% to 35%, for example. The total light transmittance is the proportion of the amount of light transmitted through a targeted object to the amount of light incident on the targeted object. For example, the total light transmittance refers to a total light transmittance measured in compliance with Japan industrial standard JIS K 7375:2008.

The upper surface of the silicone resin member 30 can be located on the same plane as the upper surface 20U (first upper surface 20U1) of the light-transmissive member 20 or can be located at a position lower than the upper surface 20U. This makes it easy to adjust the focal point position and the like of an optical system such as a reflector and a lens in the case in which the light-emitting device 100 is used for a headlight of a vehicle, for example.

### Intermediate Layer

The intermediate layer 40 is disposed between the light-transmissive member 20 and the silicone resin member 30 and can improve the adhesion therebetween. Hereinafter, a modification example of the intermediate layer 40 will be described also with reference to the optical member 80 illustrated in FIGS. 6A to 6F. The configurations of the intermediate layer 40 illustrated in FIGS. 6A to 6F can also be applied to the light-emitting devices 100 as illustrated in FIGS. 1-5.

As illustrated in FIGS. 1C, 2B, 3B, 4, 5, 6A, the intermediate layer 40A can be formed to have the same thickness throughout. This can improve the adhesion. Alternatively, the intermediate layer 40B can be formed to have partially different thicknesses. For example, when the second upper surface 20U2 and the first lateral surface 20S1 of the light-transmissive member 20 are included, the thickness of the intermediate layer 40B on the second upper surface 20U2 can be formed to be thicker than the thickness of the intermediate layer 40B on the first lateral surface 20S1 as illustrated in FIG. 6B. Thus, the time for forming the intermediate layer 40B can be shortened.

As illustrated in FIGS. 1C, 2B, 3B, 4, 5, 6A, and the like, the intermediate layer 40A can be constituted by one layer. Thus, the time for forming the intermediate layer 40 can be shortened. Alternatively, as illustrated in FIG. 6C, the intermediate layer 40C can be formed to have a structure in which two or more layers are stacked. This can further improve the adhesion as compared with the case of being constituted by one layer.

As illustrated in FIGS. 1C, 2B, 3B, 4, 5, 6A, and the like, the intermediate layer 40A can be disposed at the entirety between the light-transmissive member 20 and the silicone resin member 30. This can improve the adhesion. Alternatively, as illustrated in FIG. 6D, the intermediate layer 40D may be partially or intermittently disposed between the light-transmissive member 20 and the silicone resin member 30. In other words, the intermediate layer 40D can be disposed such that a portion of the light-transmissive member 20 and a portion of the silicone resin member 30 are in contact with each other. Thus, the time for forming the intermediate layer 40D can be shortened.

As illustrated in FIGS. 1C, 2B, 3B, 4, 5, 6A, the surface of the intermediate layer 40A can be formed to be a flat surface. Thus, light is totally reflected more efficiently on the surface of 40A than on the rough surface, so that the amount of light transmitted to the silicone resin member 30 can be reduced. Thus, in the light-emitting device illustrated in FIG. 1C or the like, the boundary between the high-luminance light-emitting region and the low-luminance light-emitting region can be clarified. In the light-emitting device illustrated in FIG. 2B or the like, the boundary between the light-emitting region and a non light-emitting region can be clarified. Alternatively, as illustrated in FIG. 6E, an intermediate layer 40E can be formed to include a surface which is a rough surface. This can further improve the adhesion. In this case, a surface roughness Sa of the surface of the intermediate layer 40E can be formed to be in a range from 0.7 μm to 0.8 μm.

As described above, the intermediate layer 40 may take a variety of forms. The position at which the intermediate layer 40 is disposed is not limited to being between the light-transmissive member 20 and the silicone resin member 30, and may be disposed at another position.

As illustrated in FIGS. 1C, 2B, 3B, 4, 6A, and the like, the intermediate layer 40A can be disposed such that the upper surface 20U (first upper surface 20U1) of the light-transmissive member 20 is exposed. Thus, variations in the thicknesses of the intermediate layer 40A that may occur when the intermediate layer 40A is disposed on the first upper surface 20U1 of the light-transmissive member 20 can be eliminated. Further, as illustrated in FIGS. 5 and 6F, the intermediate layer 40 may be disposed on the upper surface 20U (first upper surface 20U1) of the light-transmissive member 20. Thus, for example, the oxide film used as the intermediate layer 40 can function as an anti-reflective layer.

As illustrated in FIG. 4, the intermediate layer 40 may be disposed between the light-emitting element 10 and the silicone resin member 30, or between the light-emitting element 10 and a covering member 50 described later. This can also improve the adhesion between the lateral surface of the light-emitting element 10 and the silicone resin member 30 or the covering member 50. The intermediate layer 40 illustrated in FIG. 4 illustrates an example in which the intermediate layer 40 is entirely continuous. However, depending on the material or the forming method of the intermediate layer 40, the arrangement position can be variously selected, such that the intermediate layer 40 may be disposed at various positions, for example, such that the intermediate layer 40 is not formed on the lateral surface and formed only on the surface facing upward.

As illustrated in FIG. 1C, when the light-emitting device 100 includes the bonding member 70 described later, the intermediate layer 40 may be disposed between the bonding member 70 and the silicone resin member 30 or between the bonding member 70 and the covering member 50. This can also improve the adhesion between the bonding member 70 and the silicone resin member 30 or the covering member 50.

As illustrated in FIG. 1C, when the light-emitting device 100 includes the substrate 60 described later, the intermediate layer 40 may be disposed between the substrate 60 and the silicone resin member 30 or between the substrate 60 and the covering member 50. This can also improve the adhesion between the substrate 60 and the silicone resin member 30 or the covering member 50.

A method for manufacturing the intermediate layer 40 will be described. In the case of the optical member 80, first, the intermediate layer 40 can be disposed on the surface of the light-transmissive member 20. Subsequently, the silicone resin member 30 is disposed on the intermediate layer 40 in a melted state. In a case in which the intermediate layer 40 is a silane coupling agent, since the silane coupling agent is gradually cured when disposed on the surface of the light-transmissive member 20, it is necessary to dispose the silicone resin member 30 before the silane coupling agent is completely cured. For example, it is preferable to dispose the silicone resin member 30 within 90 minutes after disposing the silane coupling agent.

The intermediate layer 40 can be disposed on the surface of the light-transmissive member 20 that has been singulated in advance. When such a method is used, for example, as illustrated in FIG. 5, the intermediate layer 40 can be disposed on the upper surface 20U and the lateral surface 20S of the light-transmissive member 20. Also in the light-transmissive member 20 including the first upper surface 20U1 and the second upper surface 20U2 as illustrated in FIG. 6A or the like, when the light-transmissive member 20 that has been singulated in advance is used, the intermediate layer 40 can be disposed not only on the first lateral surface 20S1 but also on all lateral surfaces (lateral surfaces including the second lateral surface 20S2 and the lateral surface 20S continuing from the first upper surface 20U1) located at the outer periphery of the light-transmissive member 20 in a top view. This can improve the adhesion of the silicone resin member 30 or the covering member 50 across the entire lateral surface of the light-transmissive member.

In addition, in the case of the light-transmissive member 20 including the first upper surface 20U1 and the second upper surface 20U2 as illustrated in FIG. 6A or the like, the intermediate layer 40 can be disposed on the light-transmissive member 20 in a state before being singulated. Specifically, first, the light-transmissive member 20 including the first upper surface 20U1 and the second upper surface 20U2 located at a position lower than the first upper surface 20U1 is prepared. At this time, the adjacent ones of the first upper surfaces 20U1 are continuous with each other and the adjacent ones of the second upper surfaces 20U2 are continuous with each other, and the first lateral surface 20S1 is exposed. Further, the lateral surface that becomes the outer periphery of the light-transmissive member 20 after being singulated is not formed at this time.

Subsequently, the intermediate layer 40 is disposed on the second upper surface 20U2 and the first lateral surface 20S1. In this case, the intermediate layer 40 may also be disposed on the first upper surface 20U1. Subsequently, the silicone resin member 30 is disposed on the intermediate layer 40 in a melted state and then cured. Subsequently, the light-transmissive member 20 and the silicone resin member 30 are cut to obtain the singulated optical members 80.

The silicone resin member 30 can also be disposed on the first upper surface 20U1 of the light-transmissive member 20 in a melted state. In this case, a step is included in which the silicone resin is removed such that the first upper surface 20U1 is exposed. In this step, a portion of the first upper surface 20U1 may also be removed. In this case, the newly exposed surface is referred to as the first upper surface 20U1. The same applies to the upper surface 20U of the light-transmissive member 20 that does not include the second upper surface as illustrated in FIG. 5. In addition, after the intermediate layer 40 is disposed also on the 20U of the upper surface of the light-transmissive member 20, the silicone resin member 30 may be disposed so as to fill the intermediate layer 40. In this case, the silicone resin member 30 can be removed such that the upper surface 20U of the light-transmissive member 20 is exposed by removing the intermediate layer 40. Alternatively, as illustrated in FIG. 5, the silicone resin member 30 may be removed such that the intermediate layer 40 disposed on the upper surface 20U of the light-transmissive member 20 is exposed.

In addition, the light-emitting device 100 can be formed without forming the optical member 80 in advance. In this case, for example, after the light-transmissive member 20 is disposed on the upper surface of the light-emitting element 10, the intermediate layer 40 is disposed on the surface of the light-transmissive member 20, and subsequently the silicone resin member 30 is disposed. When such a method is used, as illustrated in FIG. 4, the intermediate layer 40 is also disposed on the surfaces of the light-emitting element 10, the substrate 60, and the like. When the bonding member 70 as illustrated in FIG. 1C is included, the intermediate layer 40 is disposed so as to also cover the surface of the bonding member 70.

When the silane coupling agent is used as the intermediate layer 40, the thickness of the silane coupling agent can be in a range from 0.1 μm to 15 μm. The silane coupling agent can be disposed by a spraying method, a potting method, a printing method, or the like.

When the oxide such as the oxide particles or the oxide film is used as the intermediate layer 40, the thickness of the oxide can be in a range from 0.01 μm to 1 μm. The oxide can be disposed through a sputtering method, an atomic deposition method (ALD method), a vapor deposition method, a combustion chemical vapor deposition method, or the like. The method may further include a step of washing with warm water in a range from 70° C. to 120° C. after the oxide is disposed.

### Covering Member

When the silicone resin member 30 does not cover the light-emitting element 10, the covering member 50 can be included as the member that covers the light-emitting element 10 as illustrated in FIG. 1C. The covering member 50 is a member having light reflectivity. When the light-emitting device 100 includes the bonding member 70 or the substrate 60, the covering member 50 can be disposed so as to also cover the bonding member 70 or the substrate 60. The covering member 50 may be one covering member 50 as illustrated in FIG. 2B or the like, or may be constituted by two or more covering members 50. For example, as illustrated in FIG. 1C, a second covering member 52 that covers the light-emitting element 10 and a first covering member 51 that covers the second covering member 52, the light-transmissive member 20, and the silicone resin member 30 can be included.

Examples of the covering member 50 that can be used include thermosetting resins, such as a silicone resin, a silicone-modified resin, an epoxy resin, and a phenol resin; and thermoplastic resins, such as a polycarbonate resin, an acrylic resin, a methylpentene resin, and a polynorbornene resin. The covering member 50 may be made of, for example, an inorganic material containing boron nitride or alkali metal silicate. In this case, titanium oxide or zirconium oxide can be further included.

### Bonding Member

The bonding member 70 is a member that bonds the light-emitting element 10 and the light-transmissive member 20 to each other. The bonding member 70 is disposed between the upper surface of the light-emitting element 10 and the lower surface 20D of the light-transmissive member 20. The bonding member 70 may further cover the lateral surface of the light-emitting element 10 as illustrated in FIG. 1C. As the bonding member 70, a light-transmissive resin material can be used. For example, a resin material whose main component is a thermosetting resin, such as a silicone resin, a silicone modified resin, an epoxy resin, or a phenolic resin, is preferable. The transmittance of the bonding member 70 with respect to light from the light-emitting element is preferably 70% or more, more preferably 80% or more, even more preferably 90% or more. When the light-emitting element 10 and the light-transmissive member 20 are bonded to each other through the direct bonding method, the bonding member 70 can be omitted.

### Substrate

The light-emitting device 100 can further include the substrate 60 on which the light-emitting element 10 is mounted. The substrate 60 includes a base body 61, and wiring lines 62 disposed on at least an upper surface of the base body 61. The electrode 12 of the light-emitting element 10 and the wiring line 62 are electrically connected to each other via a conductive bonding member such as solder or a bump. As illustrated in FIG. 2B, the wiring lines 62 may be disposed not only on the upper surface of the base body 61 but also on the lower surface thereof. In this case, the wiring line 62 disposed on the upper surface and the wiring line 62 disposed on the lower surface are electrically connected to each other by a via or the like.

For the base body 61, materials publicly known in the field can be used as the base body included in the wiring substrate for supporting the electronic components such as the light-emitting elements. For example, an insulating material such as glass epoxy, a resin, or a ceramic, a semiconductor material such as silicon, or a conductive material such as copper may be used. In particular, a ceramic, which has high heat resistance and light resistance, can be preferably used. Examples of a ceramic include aluminum oxide, aluminum nitride, silicon nitride, LTCC, and the like. In addition, a composite material of such an insulating material, a semiconductor material, and a conductive material may also be used. When the semiconductor material or the conductive material is used as the base body 61, the wiring line 62 can be disposed on the upper surface of the base body 61 via the insulating layer. Examples of the material of the wiring line 62 include metals such as Fe, Cu, Ni, Al, Ag, Au, Pt, Ti, W, and Pd, and alloys containing at least one of them.

The light-emitting devices according to the embodiments of the present disclosure can be preferably utilized for vehicle lighting such as headlights. In addition, the light-emitting devices according to the embodiments of the present disclosure can be utilized for the light source for a backlight of a liquid crystal display, various types of lighting fixtures, a large display, various types of display devices for advertisements, destination information, and the like, and further, a digital video camera, image reading devices in a facsimile, a copy machine, a scanner, and the like, and a projector device, for example.

What is claimed is:

1. A light-emitting device comprising:
a light-emitting element;
a light-transmissive member disposed on an upper surface of the light-emitting element and containing oxygen atoms;
a silicone resin member covering the light-transmissive member such that at least a portion of an upper surface of the light-transmissive member is exposed; and
an intermediate layer disposed between the light-transmissive member and the silicone resin member, the intermediate layer being made of a silane coupling agent.

2. The light-emitting device according to claim 1, wherein
a thickness of the intermediate layer is in a range from 0.1 μm to 15 μm.

3. The light-emitting device according to claim 1, wherein
the upper surface of the light-transmissive member includes a first upper surface, a second upper surface positioned lower than the first upper surface, and a first lateral surface between the first upper surface and the second upper surface, and
the silicone resin member covers the second upper surface and the first lateral surface of the light-transmissive member while the first upper surface is exposed.

4. The light-emitting device according to claim 3, wherein
the first upper surface is surrounded by the second upper surface in a top view.

5. The light-emitting device according to claim 1, wherein
the silicone resin member further covers a lateral surface of the light-emitting element.

6. The light-emitting device according to claim 1, wherein
the silicone resin member covers a lateral surface of the light-transmissive member.

7. A light-emitting device comprising:
a light-emitting element;
a light-transmissive member disposed on an upper surface of the light-emitting element and containing oxygen atoms;
a silicone resin member covering the light-transmissive member such that at least a portion of an upper surface of the light-transmissive member is exposed; and
an intermediate layer disposed between the light-transmissive member and the silicone resin member as an intermediate layer, the intermediate layer being made of an oxide film or oxide particles.

8. The light-emitting device according to claim 7, wherein
the oxide film or the oxide particles contain at least one selected from the group consisting of aluminum oxide, silicon oxide, and indium tin oxide.

9. The light-emitting device according to claim 7, wherein
a thickness of the intermediate layer is in a range from 0.01 μm to 1 μm.

10. The light-emitting device according to claim 7, wherein
the upper surface of the light-transmissive member includes a first upper surface, a second upper surface positioned lower than the first upper surface, and a first lateral surface between the first upper surface and the second upper surface, and
the silicone resin member covers the second upper surface and the first lateral surface of the light-transmissive member while the first upper surface is exposed.

11. The light-emitting device according to claim 10, wherein
the first upper surface is surrounded by the second upper surface in a top view.

12. The light-emitting device according to claim 7, wherein
the silicone resin member further covers a lateral surface of the light-emitting element.

13. The light-emitting device according to claim 7, wherein
the silicone resin member covers a lateral surface of the light-transmissive member.

14. An optical member comprising:
a light-transmissive member containing oxygen atoms;
a silicone resin member covering at least a part of a surface of the light-transmissive member; and
an intermediate layer disposed between the light-transmissive member and the silicone resin member, the intermediate layer being made of a silane coupling agent.

15. The optical member according to claim 14, wherein
a thickness of the intermediate layer is in a range from 0.1 μm to 15 μm.

16. An optical member comprising:
a light-transmissive member containing oxygen atoms;
a silicone resin member covering the light-transmissive member such that at least a portion of an upper surface of the light-transmissive member is exposed; and
an intermediate layer disposed between the light-transmissive member and the silicone resin member, the intermediate layer being made of an oxide film or oxide particles.

17. The optical member according to claim 16, wherein
the oxide film or the oxide particles contain at least one selected from the group consisting of aluminum oxide, silicon oxide, and indium tin oxide.

18. The optical member according to claim 17, wherein
a thickness of the intermediate layer is in a range from 0.01 μm to 1 μm.
